(19) United States
(12) Patent Application Publication
(10) Pub. No.: US 2009/0050470 A1
(43) Pub. Date: Feb. 26, 2009

(54) Method And Device For Enhancing Solderability

(75) Inventors: Tao-Chih Chang, Taoyuan County (TW); Chiao-Yun Chang, Hsinchu County (TW); Shan-Pu Yu, Taoyuan County (TW)

Correspondence Address: BEVER HOFFMAN & HARMS, LLP;2099 Gateway Place, Suite 320, San Jose, CA, 95110, US

(73) Assignee: INDUSTRIAL TECHNOLOGY RESEARCH INSTITUTE, Hsinchu (TW)

(21) Appl. No.: 12/262,002

(22) Filed: Oct. 30, 2008

Related U.S. Application Data
(62) Division of application No. 11/381,528, filed on May 3, 2006.

(30) Foreign Application Priority Data
Aug. 11, 2005 (TW) 094127400

(51) Int. Cl. B23K 1/20; C23C 14/34

(52) U.S. Cl. 204/192.11; 228/208; 228/209

(57) ABSTRACT

A method and a device for enhancing the solderability of a lead-free component are provided. The provided method is compatible with the conventional soldering process and is capable of improving the wetting ability of the solder so as to enhance the solderability and the ability of anti-oxidation thereof. Besides, it is also achievable for providing a recognizable lead-free device so as to prevent the process confusion.

### RELATED APPLICATIONS

This application is a divisional of U.S. patent application Ser. No. 11/381,528, entitled Method And Device For Enhancing Solderability” filed May 3, 2006 which claims priority to Taiwan Patent Application 094127400 filed Aug. 11, 2005.

### FIELD OF THE INVENTION

The present invention relates to a device and a method for enhancing the solderability, and more particularly, to a device and a method for enhancing the solderability for a lead-free soldering component.

### BACKGROUND OF THE INVENTION

With the improvement of living standard, more and more attention is paid for the negative effect caused by the manufacturing industry, and as a result of which, the legislation for the international environmental regulations as well as the specific practice procedures thereof are improved, where the use of hazardous substance is severely restricted thereby, so as to assure the sustained development in industry. Accordingly, the so-called “green industry” is well developed nowadays.

One principal purpose of the development of green industry is to fabricate and provide a green product, i.e. for achieving a lead-free and non-hazardous process in the electronics industry. Regarding the increasing requirements for the green industry, Restriction of Hazardous Substance (ROHS), purposed by the European Union (EU) in 2002, is the most focused one at present. Under the regulations of ROHS, it is required that from Jul. 1, 2006, the consumer electronics products to be imported into any member state of EU shall be completely lead-free. Accordingly, there are more and more international manufacturers trying to introduce the possible lead-free procedure into their existing manufacturing process for obtaining a lead-free product, so as to comply with the mentioned regulations.

Based on the mentioned, it becomes a critical issue to replace the existing lead-containing component with a lead-free one in the conventional electronics industry, which brings a series of challenges therefor.

In the conventional procedures of electronics manufacturing industry, the lead-tin alloy is typically applied for serving as the soldering component for bonding the die to a substrate or assembling a package. Under the mentioned requirements for the lead-free device, however, more efforts need to be done for the relevant techniques to obtain a further alloy that is available for replacing the conventional lead-tin alloy, so as to reduce the lead content of the soldering component and to retain the reliability in soldering and the preservability as well.

In addition to the composition of the soldering component, the improvement for solderability thereof is also regarded as a critical issue to be solved. Referring to the U.S. Pat. No. 5,086,966, a method for improving the wetting ability of a solder of lead-tin alloy and the relevant composition thereof are disclosed therein. The solder of lead-tin alloy is pretreated to deposit palladium thereon prior to soldering to a metallic substrate, which enhances the wetting of the substrate by the solder liquid during reflow, and thus a strong metallurgical bond is produced thereby.

Nevertheless, such method is developed specifically for the solder of lead-tin alloy, which apparently fails in the international tendency for lead-free demand, and thus needs to be further improved. Moreover, with the introduction of the lead-free procedure, it also needs to provide the lead-free component with a recognizable appearance for separating from the lead-containing ones in the procedure, so as to prevent the process confusion.

For overcoming the mentioned issues caused by the prior art, a method and a device for enhancing the solderability of a lead-free component are provided in the present invention. The provided method is compatible with the conventional soldering process and is capable of improving the wetting ability of the solder so as to enhance the solderability and the ability of anti-oxidation thereof. Besides, the present invention also provides a recognizable lead-free device so as to prevent the process confusion.

### SUMMARY OF THE INVENTION

In accordance with a first aspect of the present invention, a lead-free solder is provided. The provided lead-free solder includes at least a first metal and a second metal located thereon, where the oxidation potential of the second metal is higher than the oxidation potential of the first metal.

Preferably, the first metal includes tin (Sn).

Preferably, the second metal is nickel (Ni) , gold (Au), palladium (Pd), platinum (Pt) or silver (Ag).

In accordance with a second aspect of the present invention, a recognizable soldering component is provided. The provided recognizable soldering component includes at least a first metallic layer and a second metallic layer formed thereabove, wherein the second metallic layer has a color rather than that of the first metallic layer.

Preferably, the recognizable soldering component is one selecting from a group consisting of a solder ball, a bump, a pin and a terminal electrode.

Preferably, the recognizable soldering component has a lead content less than 1000 ppm.

Preferably, the first metallic layer includes tin (Sn).

Preferably, the second metallic layer is made of an inert metal.

Preferably, the inert metal includes gold (Au).

In accordance with a third aspect of the present invention, a recognizable soldering component having a relatively high solderability for connecting a die to a substrate is provided. The provided recognizable soldering component includes at least a first metallic layer and a second metallic layer located thereabove, wherein the second metallic layer has a color rather from that of the first metallic layer.

Preferably, the oxidation potential of the second metallic layer is higher than that of the first metallic layer.

In accordance with a fourth aspect of the present invention, a recognizable soldering component having a relatively high solderability for connecting a package to a board is provided. The provided recognizable soldering component includes at least a first metallic layer and a second metallic layer located thereabove, wherein the respective colors of the first and the second metallic layers are different.

Preferably, the second metallic layer has an oxidation potential higher than that of the first metallic layer.

In accordance with a fifth aspect of the present invention, a method for enhancing a solderability of a soldering component is provided. The provided method includes steps of (a) providing a lead-free bump on a die; (b) providing a metallic layer on the lead-free bump so as to form the soldering component, wherein the metallic layer has an oxidation potential higher than that of tin; and (c) bonding the die to a substrate via the soldering component.

Preferably, in the step (b), the metallic layer is formed on the lead-free bump by means of dip coating, electrocoating, electroless coating, evaporation, sputtering or chemical vapor deposition.

Preferably, the metallic layer is formed of nickel (Ni), gold (Au), palladium (Pd), platinum (Pt) or silver (Ag).

In accordance with a sixth aspect of the present invention, a method for enhancing a solderability of a device is provided. The method includes steps of: (a) forming a metallic layer on a lead-free soldering component, wherein the metallic layer has an oxidation potential higher than that of tin; and (b) applying the lead-free soldering component for bonding a package to a board.

Preferably, in the step (a), the metallic layer is formed on the lead-free soldering component by means of dip coating, electrocoating, electroless coating, evaporation, sputtering and chemical vapor deposition.

Preferably, the metallic layer is formed of nickel (Ni), gold (Au), palladium (Pd), platinum (Pt) or silver (Ag).

Preferably, the soldering component is one selecting from a group consisting of a solder ball, a bump, a pin and a terminal electrode.

The foregoing and other features and advantages of the present invention will be more clearly understood through the following descriptions with reference to the drawings, wherein:

### BRIEF DESCRIPTION OF THE DRAWINGS

FIG. 1 is a flowchart for illustrating steps of the method for enhancing the solderability for bonding a die to a substrate according to the present invention;

FIGS. 2(a) and 2(b) are diagrams illustrating a further application according to a first preferred embodiment of the present invention;

FIGS. 3(a) and 3(b) are diagrams illustrating a further application according to a second preferred embodiment of the present invention;

FIG. 4 is a diagram illustrating a further application according to a third preferred embodiment of the present invention;

FIG. 5 is a flowchart for illustrating steps of the method for enhancing the solderability for bonding a package to a board according to the present invention;

FIG. 6 is a diagram illustrating a further application according to a fourth preferred embodiment of the present invention;

FIG. 7 is a diagram illustrating a further application according to a fifth preferred embodiment of the present invention;

FIGS. 8(a) and 8(b) are diagrams for showing the respective result of solderability test for the conventional lead-free component and the novel lead-free component provided by the present invention; and

FIGS. 9(a) and 9(b) are diagrams for showing the respective appearance for the conventional lead-free component and the novel lead-free component provided by the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

The present invention provides a novel method and the relevant device for enhancing the solderability. More specific, the present invention provides a method and a relevant lead-free device for enhancing the solderability and the wetting ability of the soldering component used therein, and thereby the lead-free device would be more recognizable and discernable so as to prevent the possible confusion while the lead-free procedures are introduced into the existing process.

In a preferred embodiment of the present invention, a typical dip coating is applied for depositing a metallic layer of a relatively high oxidation potential, i.e. an oxidation potential higher than that of tin (Sn), onto the surface of a lead-free solder component. Owing to the relatively high oxidation potential, the metallic layer is formable through a spontaneous replacement reaction occurring on the surface of the lead-free solder component, and thereby a passivation layer is fabricated so as to improve the anti-oxidation ability and thus the preservability of the lead-free device.

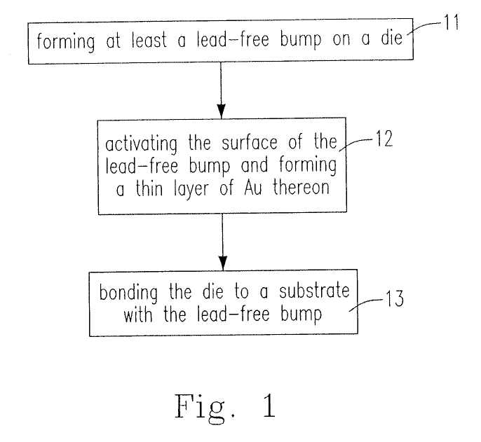

Please refer to FIG. 1, which is a flowchart for illustrating steps of the method for enhancing the solderability according to the present invention. In this embodiment, preferably, the method is applied for bonding a die to a substrate. First, at least a lead-free bump is provided on the die, as shown in the step 11. After activating the surface of the lead-free bump, a thin layer of gold is formed thereon by means of typical dip coating, as shown in the step 12. Afterward, the die is bonded to a desired substrate via the lead-free bump having the thin layer of gold thereon, as shown in the step 13, and thus the present lead-free soldering component having a relatively high solderability and anti-oxidation ability is fabricated.

In this embodiment of the present invention, it is preferred, but not restricted, to form a thin layer of gold on the surface of the lead-free bump. Moreover, the electrocoating, electroless coating, evaporation, sputtering and chemical vapor deposition (CVD) that are typically available for film deposition are also applicable and compliable with the method according to the present invention. In addition to the thin layer of gold, it is also applicable to deposit a thin layer of nickel (Ni), silver (Ag), palladium (Pd) or platinum (Pt) onto the surface of the lead-free bump for serving as the passivation layer thereof. For separating from the conventional lead-containing components in the process, a recognizable thin layer whose color is different from that of the bump is more preferable in this case.

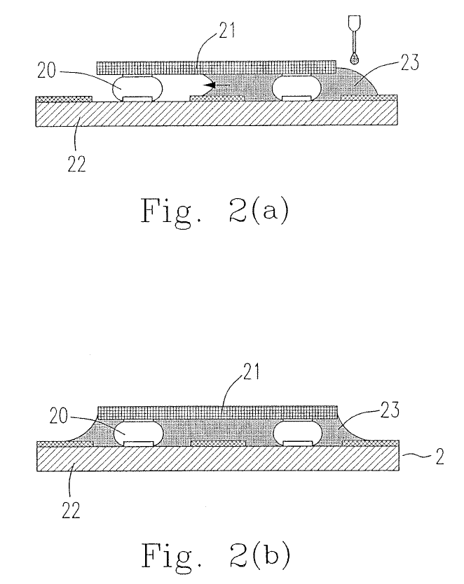

Please refer to FIGS. 2(a) and 2(b), which are diagrams illustrating a further application according to a first preferred embodiment of the present invention. In this embodiment, the soldering component according to the present invention is combined with an underfill procedure for packaging. More specifically, the lead-free bump having a thin layer of gold dip-coated thereon 20 is applied for bonding a die 21 to a substrate 22, and subsequently, the bonder 23 is dropped thereto, so as to fabricate a lead-free package structure 2.

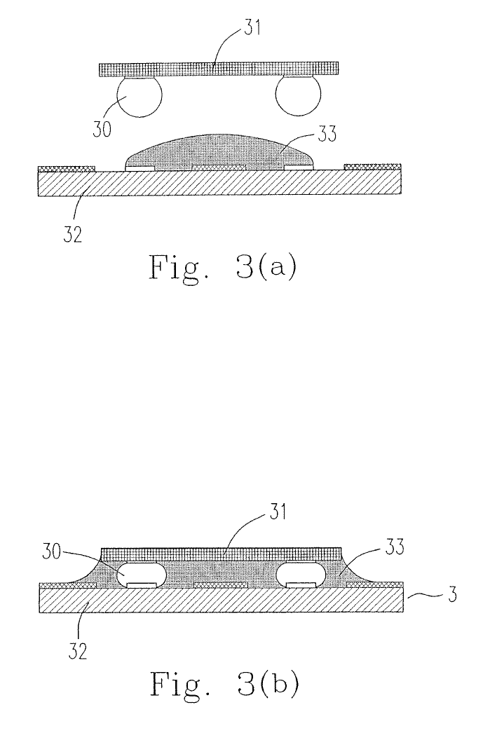

Please refer to FIGS. 3(a) and 3(b), which are diagrams illustrating a further application according to a second preferred embodiment of the present invention. In this embodiment, the soldering component according to the present invention is combined with a no-flow underfill procedure for packaging. In more specifics, the lead-free bump having a thin layer of gold dip-coated thereon 30 is applied for bonding a die 31 to a substrate 32 which is covered with the bonder 33, so as to fabricate a lead-free package structure 3.

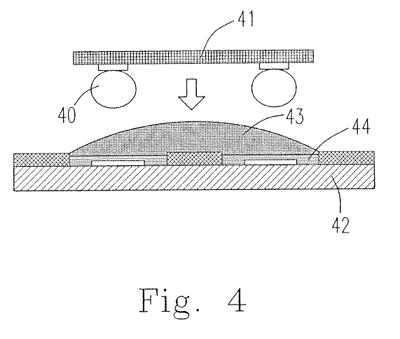

The present invention is advantageous in that an additional preflux is applicable for further increasing the bonding reliability for the soldering component. Please refer to FIG. 4, which is a diagram illustrating a further application according to a third preferred embodiment of the present invention. Similarly, the no-flow underfill procedure is adopted in this case for the die packaging. That is, the lead-free bump having a thin layer of gold dip-coated thereon 40 is applied for bonding a die 41 to a substrate 42 which is covered with the bonder 43, so as to fabricate a lead-free package structure 4. Moreover, in order to improve the bonding ability for the lead-free package structure 4, a preflux layer 44 is pre-formed on the surface of the binding point of the substrate 42. In addition to the preflux layer 44, it is also applicable in the present invention for carrying out the procedures of such as immersion Sn, immersion Ag and ENIG (electroless nickel/immersion gold) or the procedure of organic solderability preservative (OSP) coating, so as to improve the preservability of the lead-free package structure.

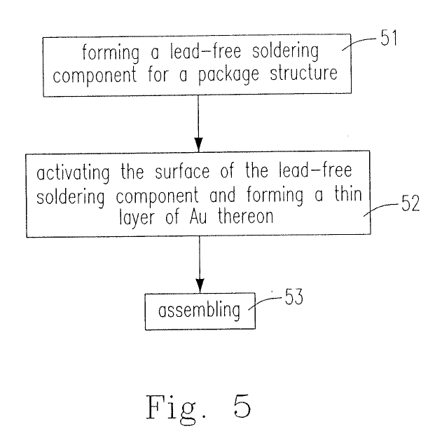

Similarly, the method according to the present invention is also adoptable for mounting a package structure onto a desired board. Please refer to FIG. 5, which is a flowchart for illustrating steps of the method for enhancing the solderability for assembling the package according to the present invention. In this embodiment, a lead-free soldering component for assembling the package is first fabricated from the lead-free solder, as shown in the step 51. After the surface of the lead-free soldering component is activated, it is provided with a thin layer of gold thereon, as shown in the step 52. Subsequently, the package structure is mounted onto a desired board, so as to fabricate the assembled lead-free device having a relatively high solderability and anti-oxidation ability, as shown in the step 53.

In this embodiment, preferably, the lead-free soldering component is a bump, a solder ball, a pin or a terminal electrode. Moreover, the electrocoating, electroless coating, evaporation, sputtering and chemical vapor deposition (CVD) that are typically available for film deposition are also applicable and compliable with the method according to the present invention. In addition to the thin layer of gold, it is also applicable to deposit a thin layer of nickel (Ni), silver (Ag), palladium (Pd) or platinum (Pt) onto the surface of the lead-free soldering component for serving as a passivation layer thereof.

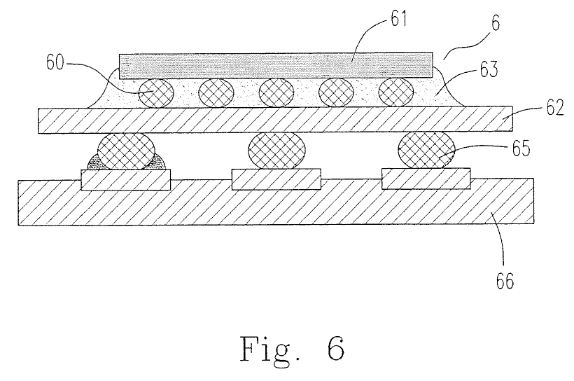

Please refer to FIG. 6, which is a diagram illustrating a further application according to a fourth preferred embodiment of the present invention. In this embodiment, the lead-free bump having a thin layer of gold dip-coated thereon 60 is applied for bonding a die 61 to a substrate 62 which is covered with the bonder 63, so as to fabricate a lead-free package structure. Moreover, the lead-free package structure is assembled by means of flip-chip, so as to fabricate a lead-free device 6. According to the present invention, the surface of the lead-free device 6 is further provided with a led-free terminal having a thin layer of gold coated thereon 65, and thereby the lead-free device 6 is connected to a desired board 66.

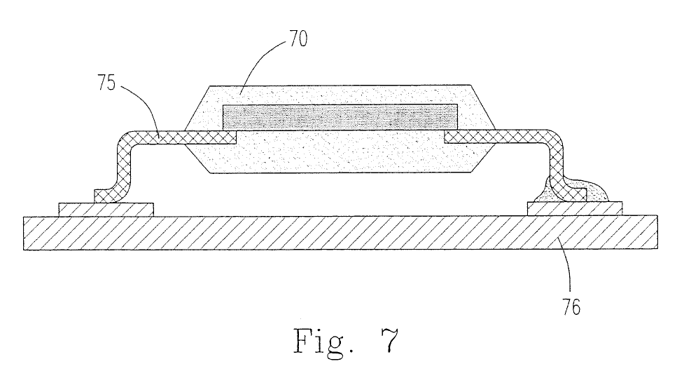

Please refer to FIG. 7, which is a diagram illustrating a further application according to a fifth preferred embodiment of the present invention. In this embodiment, the pin 75 for connecting the lead-free package structure 70 to the desired board 76 is coated with a thin layer of gold, so that the anti-oxidation ability and the recognizability thereof would be significantly improved.

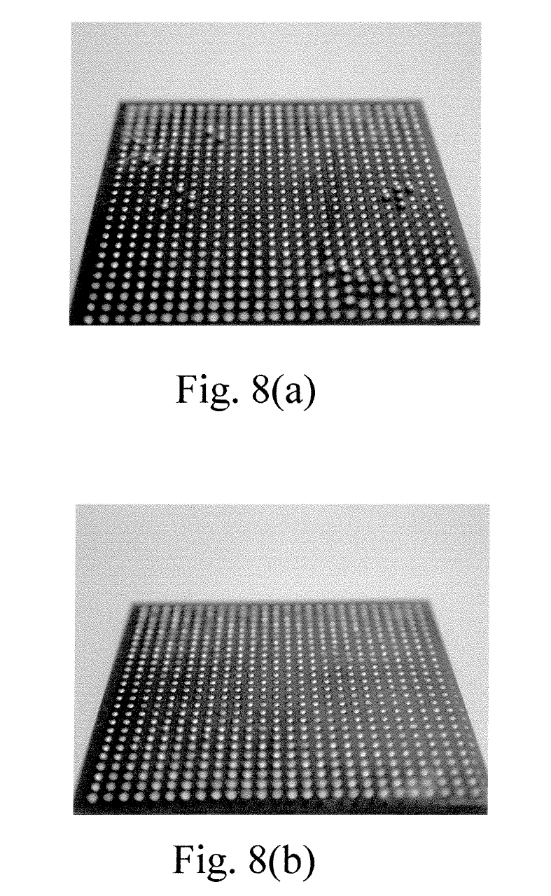

Please refer to FIGS. 8(a) and 8(b), which are diagrams for showing the respective result of solderability test for the conventional lead-free component and the novel lead-free component provided by the present invention. In comparison with the conventional lead-free component as shown in FIG. 8(a), the lead-free component according to the present invention exhibits a more superior wetting ability, where the wetting reaction occurs in the whole test region of the substrate, as shown in FIG. 8(b).

In the preferred embodiment, by performing a dip-coating with a commercial chemical of electroless gold for printed circuit board (PCB) under a temperature below 90° C. for approximately 10 minutes, a thin layer of gold having a thickness of approximately 0.25 μm would be obtained on the surface of the lead-free component. More specifically, since the oxidation potential of gold is higher than that of the base material, tin, of the lead-free component, a spontaneous replacement reaction would occur on the surface of the lead-free component upon dip-coating, and a thin layer of gold may thus formed thereon. Moreover, the thin layer of gold also provides an excellent protection for the lead-free component owing to its relatively high oxidation potential, and therefore, the ability in anti-oxidation of the lead-free component may significantly improved thereby. Furthermore, based on the test result, the lead-free component according to the present invention also exhibits a superior ability in wetting and an improved solderability.

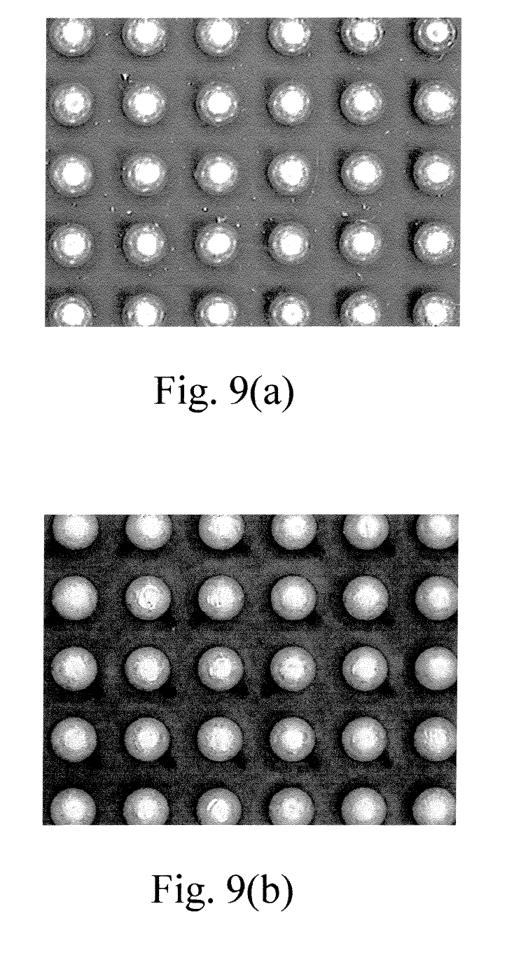

Please refer to FIGS. 9(a) and 9(b), which are diagrams for showing the respective appearance for the conventional lead-free component and the novel lead-free component provided by the present invention. In addition to the mentioned efforts, the lead-free component according to the present invention is further advantageous in the recognizable appearance thereof since the color of gold is different from that of the conventional lead-containing component, whereby the process confusion could be prevented while the lead-free procedure is introduced in a conventional procedure. Hence, the present invention not only has a novelty and a progressive nature, but also has an industry utility.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method for enhancing a solderability of a soldering component, comprising the steps of:
(a) forming a lead-free bump on a die;
(b) forming a metallic layer on said lead-free bump so as to form said soldering component, wherein said metallic layer has an oxidation potential higher than that of tin; and
(c) bonding said die to a substrate via said soldering component.

2. The method according to claim 1, wherein in said step (b), said metallic layer is formed on said lead-free bump by means of one selected from a group consisting of a dip coating, an electrocoating, an electroless coating, an evaporation, a sputtering and a chemical vapor deposition.

3. The method according to claim 1, wherein said metallic layer is formed of one selected from a group consisting of a nickel, a gold, a palladium, a platinum and a silver.

4. A method for enhancing a solderability of a device, comprising the steps of:
(a) forming a metallic layer on a lead-free soldering component, wherein said metallic layer has an oxidation potential higher than that of tin; and
(b) applying said lead-free soldering component for bonding a package to a board.

5. The method according to claim 4, wherein in said step (a), said metallic layer is formed on said lead-free soldering component by means of one selected from a group consisting of a dip coating, an electrocoating, an electroless coating, an evaporation, a sputtering and a chemical vapor deposition.

6. The method according to claim 4, wherein said metallic layer is formed of one selected from a group consisting of a nickel, a gold, a palladium, a platinum and a silver.

7. The method according to claim 4, wherein said soldering component is one selecting from a group consisting of a solder ball, a bump, a pin and a terminal electrode.
